(19) United States
(12) Patent Application Publication
(10) Pub. No.: US 2007/0218592 A1
(43) Pub. Date: Sep. 20, 2007

(54) Green Sheet, Production Method of Green Sheet and Production Method of Electronic Device

(75) Inventors: Hisashi Kobayashi, Narita-shi (JP); Shigeki Sato, Narita (JP)

Correspondence Address: OLIFF & BERRIDGE, PLC, P.O. BOX 19928, ALEXANDRIA, VA, 22320, US

(73) Assignee: TDK Corporation, Tokyo (JP)

(21) Appl. No.: 11/596,810

(22) PCT Filed: May 18, 2005
(86) PCT No.: PCT/JP05/09030

§ 371 Date: Nov. 17, 2006

(30) Foreign Application Priority Data
May 20, 2004 (JP) 2004-150504

(51) Int. Cl. H01L 21/00

(52) U.S. Cl. 438/127; 264/128

(57) ABSTRACT

A production method, comprising the steps of preparing a pre-compression green sheet including ceramic powder and a binder resin and compressing the pre-compression green sheet to obtain compressed green sheet: wherein a difference (Δρg) between a pre-compression sheet density (ρg1) of the pre-compression green sheet and a post-compression sheet density (ρg2) of the compressed green sheet is expressed by Δρg=ρg2−ρg1, and a sheet contraction rate (Δρg/ρg1) as a ratio of the difference (Δρg) to the pre-compression sheet density (ρg1) is 1% or higher.

### TECHNICAL FIELD

The present invention relates to a green sheet having an excellent sheet cutting property (strong enough to be cut), excellent breathability, handleability and, particularly, high adhesiveness (release strength), a production method thereof and a production method of an electronic device using the green sheet.

### BACKGROUND ART

To produce a ceramic electronic device, such as a CR built-in substrate and multilayer ceramic capacitor, normally, ceramic slurry composed of ceramic powder, a binder (an acrylic resin and butyral resin, etc.), plasticizer and an organic solvent (toluene, MEK) is prepared first. Next, the ceramic slurry is applied on a PET film by using the doctor blade method, etc., heated to dry, then, the PET film is removed, so that a ceramic green sheet is obtained. Next, an internal electrode is printed on the ceramic green sheet and dried. The results are stacked and cut in a chip shape to obtain green chips. After firing the green chips, terminal electrodes are formed to produce electronic devices, such as multilayer ceramic capacitors.

When producing a multilayer ceramic capacitor, based on a desired capacitance required as a capacitor, an interlayer thickness of a sheet, on which an internal electrode is formed, is in a range of 1 μm to 100 μm or so. Also, in a multilayer ceramic capacitor, a part without an internal electrode is formed on its outer part in the stacking direction of the capacitor chip.

A thickness of an outer part of a dielectric layer corresponding to the part without being formed an internal electrode layer has to be relatively thick as several tens of μm to several hundreds of μm to protect the internal structure. Therefore, this part is formed by stacking a plurality of relatively thick ceramic green sheets, on which an internal electrode is not printed. Accordingly, when forming this outer part by using a thin layer green sheets, the number of layers to be stacked increases and the number of production steps increases, which lead to an increase of the production coat.

As the number of dielectric layers in one-chip capacitor becomes large, the capacitance becomes larger, however, a size of the chip is limited, so the dielectric layers have to be thin. The dielectric layers are obtained by covering dielectric particles having a particle diameter of sub-micron order with a resin (binder), forming a sheet, stacking the results and firing. Producing of thin green sheets leads to an attainment of thin dielectric layers.

As explained above, a ceramic part used in the multilayer chip capacitor has a cover part (outer layer) for protecting an exterior of the chip in addition to the dielectric layers (inner layers) for obtaining capacitance. While the inner layers are required to be thin, the outer layers have to have a certain thickness for protecting the internal structure.

Accordingly, it is liable that the inner layers and outer layers are respectively required to have mutually different capabilities, for example, the inner layers are required to have precision and smoothness, etc. and the outer layers are required to have breathability and a cutting property, etc. On the other hand, in terms of production reasons and reliability, both of the inner layers and outer layers are required to have an improved handleability, such as high adhesiveness.

Thus, for example, in the patent article 1 below, adhesiveness aids are added to the outer layer green sheet to improve adhesiveness of the outer layer green sheet. However, in the method in the patent article 1, a binder resin composition of the outer layer green sheets becomes different from a composition of the inner layer green sheets as a result of adding the adhesiveness aids. This leads to a result that binder removal reaction arises at different timing between the inner layers and the outer layers in the binder removal step by heating the green chip, strength of the chip declines and cracks and other damages may be caused.

[Patent Article 1] The Japanese Unexamined Patent Publication No. 2000-133547

### DISCLOSURE OF THE INVENTION

### Problem to be Solved by the Invention

The present invention was made in consideration of the above circumstances and has as an object thereof to provide a green sheet having an excellent sheet cutting property (strong enough to be cut), excellent breathability, handleability and, particularly, high adhesiveness (release strength), a production method thereof and a production method of an electronic device using the green sheet.

### MEANS FOR SOLVING THE PROBLEM

To attain the above objects, according to the present invention, there is provided a production method of a green sheet, comprising the steps of:

preparing a pre-compression green sheet including ceramic powder and a binder resin; and

compressing the pre-compression green sheet to obtain a compressed green sheet;

wherein

a difference (Δρg) between a pre-compression sheet density (ρg1) of the pre-compression green sheet and a post-compression sheet density (ρg2) of the compressed green sheet is expressed by Δρg=ρg2−ρg1; and

a sheet contraction rate (Δρg/ρg1) as a ratio of the difference (Δρg) to the pre-compression sheet density (ρg1) is 1% or higher.

In the present invention, by compressing the pre-compression green sheets to give a sheet contraction rate (Δρg/ρg1) of 1% or higher, preferably 1.2% or higher, it is possible to improve various characteristics of compressed green sheets, particularly, adhesiveness (release strength). By improving adhesiveness of the green sheets, for example, physical strength of green chips before being fired and stacked body after firing, particularly, a decrease of cracks can be attained. It is liable that the higher the sheet contraction rate (Δρg/ρg1) is, the more enhanced the effects of the present invention and more preferable, however, normally 35% or so is the upper limit in the compression method.

Preferably, a compression force in the step of compressing the pre-compression green sheets is 1 to 200 MPa, more preferably 2 to 200 MPa. When the compression force is too small, it is liable that the sheet contraction rate (Δρg/ρg1) becomes too low and effects of the present invention cannot be obtained. Inversely, when the compression force is too large, the green sheets tend to be broken.

A compression time in the compression step is preferably 5 seconds to 60 minutes, and a compression temperature is preferably 50 to 100° C. When the compression time is too short, it is liable that the sheet contraction rate (Δρg/ρg1) becomes too low and effects of the present invention cannot be obtained. Inversely, when it is too long, it is liable that the production efficiency declines and green sheets are broken. Also, when the compression temperature is too low, it is liable that the sheet contraction rate (Δρg/ρg1) becomes too low and effects of the present invention cannot be obtained. Inversely, when the compression temperature is too high, it is liable that a binder in the green sheets becomes soft due to heating and it becomes difficult to keep the sheet shape.

Preferably, a thickness of the pre-compression green sheet is 1 to 30 μm, more preferably, 2 to 25 μm. When the thickness of the pre-compression green sheet is too thin, the sheet contraction rate (Δρg/ρg1) becomes hard to be improved by compression, while when too thick, it is liable that molding to a sheet becomes difficult and preferable sheet characteristics cannot be obtained.

Preferably, ceramic powder having an average particle diameter (D50 diameter) of 0.1 to 1.0 μm, more preferably, 0.2 to 0.8 μm is used as the ceramic powder explained above. In the present invention, the average particle (D50 diameter) means an average particle diameter at 50% of entire volume of the ceramic powder and is defined, for example, by JIS R 1629, etc. Note that an average particle diameter (D50 diameter) of the ceramic powder means an average particle diameter in a state of being actually included in the green sheets and, for example, when pulverizing a material powder, an average particle diameter after the pulverization is adjusted to be in the above range.

When an average particle diameter (D50 diameter) of the ceramic powder is too small, the sheet contraction rate (Δρg/ρg1) becomes hard to be improved by compression, while when too large, a condition of the sheet surface tends to decline.

Preferably, a content of the binder resin in the pre-compression green sheet is 4 to 6.5 parts by weight, more preferably, 4 to 6 parts by weight with respect to 100 parts by weight of the ceramic powder. When an adding quantity of the binder resin in the pre-compression green sheet is too small, it is liable that sufficient adhesive strength cannot be obtained in terms of molding and processing a sheet, while when too large, strength of the sheet tends to become too large.

Preferably, the production method of the present invention further comprises the steps of:

preparing green sheet slurry including the ceramic powder, the binder resin and a solvent; and

forming the pre-compression green sheet by using the green sheet slurry;

wherein:

the binder resin includes a butyral based resin as its main component;

the solvent includes a good solvent medium for the binder resin to be dissolved well and a poor solvent medium giving poorer solubility to the binder resin comparing with the good solvent medium; and

the poor solvent medium is included in a range of 20 to 60 wt % with respect to entire solvent.

In the present invention, the poor solvent medium is defined as a solvent medium which does not allow the binder resin to be dissolved therein at all, a solvent medium which almost does not allow the same to be dissolved but a little, or a solvent medium which does not allow the same to be dissolved but makes the same swell. On the other hand, the good solvent medium is solvent mediums other than the poor solvent medium and allows the binder resin to be dissolved well.

In the present invention, as a result that the solvent includes a predetermined amount of the poor solvent medium in addition to the good solvent medium, sheet cutting property and sheet breathability can be improved, handleability can be furthermore improved and, particularly, adhesive strength can be improved.

Furthermore, in the present invention, as a result that the solvent includes a predetermined amount of the poor solvent medium, a pre-compression sheet density (ρg1) of the pre-compression green sheet can become low. By compressing the low density pre-compression green sheet to obtain a compressed green sheet, a difference (Δρg) of sheet densities before and after the compression can be large and the sheet contraction rate (Δρg/ρg1) can be improved. Note that, in the present invention, to attain a low density of the green sheet means, for example, the sheet density of a molded green sheet becomes low when using a ceramic powder having the same density. An extent of the low density of the green sheet is not particularly limited but, for example, a ratio (ρg1/ρ0) of a pre-compression sheet density (ρg1) of the pre-compression green sheet to a density (ρ0) of the ceramic powder is 0.5 to 0.65 or so.

The poor solvent medium preferably includes a solvent medium having a high boiling point than that of the good solvent medium and, it is particularly preferable to include at least one of toluene, xylene, mineral spirits, benzyl acetate, solvent naphtha, industrial gasoline, kerosene, cyclohexanone, heptanone and ethylbenzene.

Note that when mineral spirits (MSP) is included as the poor solvent medium, it is preferable that the mineral spirits alone is included in a range of larger than 7% but not larger than 15% with respect to the entire solvent. When the adding quantity of MSP is too small, breathability tends to decline, while when the adding quantity is too large, it is liable that the sheet surface smoothness declines.

The good solvent medium is preferably alcohol and, for example, methanol, ethanol, propanol and butanol, etc. may be mentioned.

In the present invention, the poor solvent medium is included in a range of preferably 20 to 60 wt %, more preferably 20 to 50 wt %, and furthermore preferably 30 to 50 wt % with respect to the entire solvent. When the weight % of the poor solvent medium is too small, the effects of adding the poor solvent medium in the solvent become poor, while when too large, it is liable that the 6 filtering property of the green sheet slurry tends to decline.

Preferably, the butyral resin is a polyvinyl butyral resin, a polymerization degree of the polyvinyl butyral resin is 1000 or higher and 1700 or lower, a butyralation degree of the resin is higher than 64% and lower than 78%, and a residual acetyl group amount is lower than 6%.

When the polymerization degree of the polyvinyl butyral resin is too low, it is liable that sufficient mechanical strength is hard to be obtained. While, when the polymerization degree is too high, surface roughness tends to decline when made to be a sheet. Also, when the butyralation degree of the polyvinyl butyral resin is too low, solubility to slurry tends to decline, while when too high, sheet surface roughness tends to decline. Furthermore, when the residual acetyl group amount is too large, the sheet surface roughness tends to decline.

The green sheet according to the present invention is produced by any one of the above methods.

According to the present invention, there is provided a production method of an electronic device, comprising the steps of:

stacking internal electrode layers and green sheets to obtain a green chip; and

firing the green chip;

wherein the green sheet of the above inventions is used as at least a part of said green sheet.

In the production method of an electronic device of the present invention, the green sheet of the present invention explained above is used as at least a part of the green sheet, so adhesive strength of a green chip before being fired, a decrease of cracks on a stacked body after firing and an improvement of handleability can be attained.

In the production method of an electronic device of the present invention, among the green sheets, it is preferable to use the green sheet of the present invention as at least a part of the outer green sheets for composing the outer dielectric layers. Particularly, by using the green sheet of the present invention as the outer green sheet, precision of the outer dielectric layer (cover part) after firing can be improved, cracks on the green chip before being fired and stacked body after firing can be decreased, and handleability can be improved.

Alternately, according to the present invention, there is provided a production method of an electronic device, comprising the steps of:

stacking internal electrode layers and green sheets to obtain a green chip; and

firing the green chip;

wherein:

a difference (Δρg) between a pre-compression sheet density (ρg1) of the green sheet before compression and a post-compression sheet density (ρg2) of the green sheet after compression is expressed by Δρ=ρg2−ρg1; and

a compression force is applied to the green sheets, so that a sheet contraction rate (Δρg/ρg1) as a ratio of the difference (Δρg) to the pre-compression sheet density (ρg1) becomes 1% or higher.

In the production method of an electronic device of the present invention, it is sufficient that the green sheets are compressed to give a sheet contraction rate (Δρg/ρg1) in the predetermined range as above in a state of being included in the green chip before firing. Accordingly, for example, the sheets may be compressed one by one at the time of stacking the green sheets, or a plurality of sheets may be compressed at a time as the inner stacked body and outer stacked body after stacking or the green chip before firing.

In the production method of an electronic device of the present invention, among the green sheets, it is preferable to apply a compression force to the outer green sheets, so that the sheet contraction rate (Δρg/ρg1) of the outer green sheets for composing the outer dielectric layer becomes 1% or higher. Particularly, by applying a compression force to the outer green sheets to give a sheet contraction rate (Δρg/ρg1) of 1% or higher, precision of the outer dielectric layers (cover part) after firing can be improved, cracks on the green chip before firing and stacked body after firing can be decreased, and handleability can be improved.

An electronic device to be produced by the present invention is not particularly limited and a multilayer ceramic capacitor, piezoelectric element, chip inductor and other surface mounted (SMD) chip type electronic devices may be mentioned.

### EFFECTS OF THE INVENTION

According to the present invention, by controlling the sheet contraction rate (Δρg/ρg1) to be in a predetermined range, it is possible to provide a green sheet having an excellent sheet cutting property (strong enough to be cut), excellent breathability, excellent handleability and, particularly, high adhesiveness (release strength). Furthermore, according to the present invention, a production method of an electronic device using the green sheet can be provided.

### BRIEF DESCRIPTION OF DRAWINGS

FIG. 1 is a schematic sectional view of a multilayer ceramic capacitor according to an embodiment of the present invention.

FIG. 2 is a sectional view of a key part of a green sheet used in a production procedure of the capacitor shown in FIG. 1.

FIG. 3 is a sectional view of a key part of a green sheet multilayer body used in a production procedure of the capacitor shown in FIG. 1.

FIG. 4 is a graph showing a relationship of a sheet contraction rate (Δρg/ρg1) and release strength.

### BEST MODE FOR WORKING THE INVENTION

Below, the present invention will be explained based on embodiments shown in drawings.

First, as an embodiment of an electronic device produced by using the green sheet according to the present invention, an overall configuration of a multilayer ceramic capacitor will be explained.

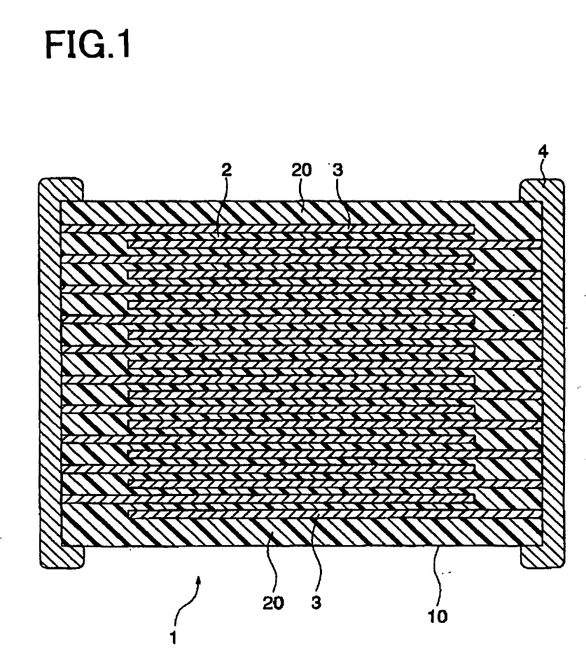

As shown in FIG. 1, the multilayer ceramic capacitor 1 has a capacitor element body 10 configured by alternately stacking inner dielectric layers 2 and internal electrode layers 3. On both end portions of the capacitor element body 10, a pair of terminal electrodes 4 are formed and conduct with the internal electrode layers 3 alternately arranged inside the element body 10. A shape of the capacitor element body 10 is not particularly limited and is normally a rectangular parallelepiped. Also, the size is not particularly limited and may be a suitable size in accordance with the use purpose, but is normally a length (0.6 to 5.6 mm, preferably 0.6 to 3.2 mm)×width (0.3 to 5.0 mm, preferably 0.3 to 1.6 mm)×thickness (0.1 to 1.9 mm, preferably 0.3 to 1.6 mm) or so.

The internal electrode layers 3 are stacked, so that end surfaces of both aides are exposed alternately to surfaces of two facing end portions of the capacitor element body 10. The pair of terminal electrodes 4 are formed at both end portions of the capacitor element body 10 and connected to the exposed end surfaces of the alternately arranged internal electrode layers 3 so as to configure a capacitor circuit.

In the capacitor element body 10, both outer end portions in the stacking direction of the internal electrode layers 3 and the inner dielectric layers 2 are arranged with outer dielectric layers 20 to protect inside of the element body 10.

Dielectric Layers 2 and 20

A composition of the inner dielectric layers 2 and outer dielectric layers 20 is not particularly limited in the present invention and they are composed, for example, of a dielectric ceramic composition including a dielectric material, such as calcium titanate, strontium titanate and/or barium titanate.

Note that the number of stacked layers, thickness and other condition of the inner dielectric layers 2 shown in FIG. 1 may be suitably determined in accordance with the use object, but in the present embodiment, a thickness of the inner dielectric layer 2 is made 1 μm to 50 μm or so, preferably 5 μm or thinner, and more preferably 3 μm or thinner. Also, a thickness of the outer dielectric layer 20 is, for example, 100 μm to several hundreds of μm or so.

Internal Electrode Layer 3

A conductive material included in the internal electrode layer 3 is not particularly limited, but since components of the inner dielectric layer 2 has reduction-resistance, base metals may be used. As base metals to be used as the conductive material, N1, Cu, a N1 alloy or Cu alloy is preferable. When a main component of the inner electrode layer 3 is Ni, a method of firing in a low oxygen partial pressure (reducing atmosphere) is used, so that the dielectric is not reduced. On the other hand, a method of making a composition ratio of the dielectric deviated from the stoichiometric composition, etc. is used so as not to make the dielectric reduced.

A thickness of the internal electrode layer 3 may be suitably determined in accordance with the use object, etc., but normally it is 0.5 to 5 μm or so.

Terminal Electrode 4

A conductive material to be included in the terminal electrodes 4 is not particularly limited and normally Cu, a Cu alloy, N1 or a N1 alloy, etc. is used. Note that Ag and an Ag—Pd alloy, etc. may be also used. Note that in the present embodiment, inexpensive N1, Cu and alloys of them may be used.

A thickness of the terminal electrodes may be suitably determined in accordance with the use object, etc. but normally 10 to 50 μm or so is preferable.

Production Method of Multilayer Ceramic Capacitor

Next, a production method of a multilayer ceramic capacitor according to an embodiment of the present invention will be explained.

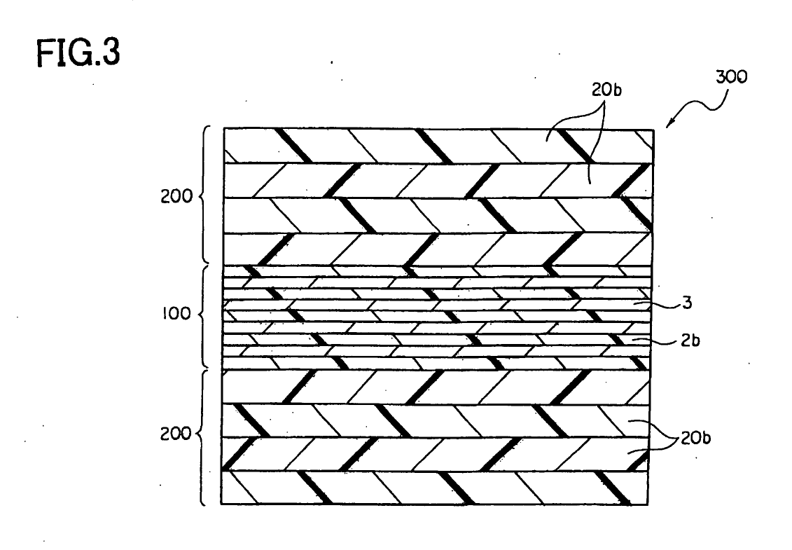

In the production method of the present embodiment, first, an inner stacked body 100 to compose the inner dielectric layers 2 and the internal electrode layers 3 shown in FIG. 1 after firing is produced. Next, outer stacked bodies 200 to compose the outer dielectric layers 20 shown in FIG. 1 are stacked on both end portions in the stacking direction of the inner stacked body 100 so as to obtain a green sheet stacked body 300 shown in FIG. 3. The stacked body is cut in a predetermined size to obtain a green chip and, then, binder removal processing 6 and firing are performed.

Production of Green Sheet slurry

First, green sheet slurry for producing respective green sheets (inner green sheets and outer green sheets) to form the inner dielectric layers 2 and the outer dielectric layers 20 is produced.

The green sheet slurry is composed of an organic solvent based slurry obtained by kneading a dielectric material (ceramic powder) and an organic vehicle.

The dielectric material may be suitably selected from composite oxides or a variety of compounds to be oxides, for example, carbonate, nitrate, hydroxide and organic metal compound, etc., and mixed for use.

The dielectric material (ceramic powder) of the green sheet slurry preferably has an average particle diameter (D50 diameter) of 0.1 to 1.0 μm, and more preferably 0.2 to 0.8 μm or so. In the present embodiment, the average particle diameter (D50 diameter) means an average particle diameter at 50% of the entire volume of the ceramic powder and is defined, for example, by JIS R 1629, etc. When the average particle diameter (DS0 diameter) of the ceramic powder is too small, an improvement of the sheet contraction rate (Δρg/ρg1) by compression tends to become hard, while when too large, the surface condition of the sheet tends to be deteriorated.

An organic vehicle is obtained by dissolving a binder resin in an organic solvent. The binder resin to be used for the organic vehicle in the present embodiment is a polyvinyl butyral resin. A polymerization degree of the polyvinyl butyral resin is 1000 or higher and 1700 or lower, and preferably, 1400 to 1700. Also, a butyralation degree of the resin is higher than 64% and lower than 78%, preferably, higher than 64% and 70% or lower. The residual acetyl group amount is smaller than 6% and preferably 3% or smaller.

A polymerization degree of the polyvinyl butyral resin can be measured, for example, from a polymerization degree of a polyvinyl acetal resin as the material. Also, a butyralation degree can be measured, for example, based on JIS K 6728. Furthermore, the residual acetyl group amount can be measured based on JIS K 6728.

When the polymerization degree of the polyvinyl butyral resin is too low, for example, in the case of making the green sheet to be 5 μm or thinner and preferably 3 μm or thinner, it is liable that sufficient mechanical strength is hard to be obtained. While, when the polymerization degree in too high, surface roughness tends to decline when made to be a sheet. Also, when the butyralation degree of the polyvinyl butyral resin is too low, solubility to slurry tends to decline, while when too high, sheet surface roughness tends to decline. Furthermore, when the residual acetyl group amount is too large, the sheet surface roughness tends to decline.

An organic solvent to be used for the organic vehicle of the green sheet slurry preferably includes a good solvent medium for the binder resin to be dissolved well and a poor solvent medium giving poorer solubility to the binder resin comparing with the good solvent medium. The poor solvent medium is included in a range of 20 to 60 wt % with respect to the entire solvent. Moreover, the poor solvent medium includes a solvent medium having a higher boiling point than that of the good solvent medium.

The good solvent medium is, for example, alcohol, and the poor solvent medium includes at least one of toluene, xylene, mineral spirits, benzyl acetate, solvent naphtha, industrial gasoline, kerosene, heptanone and ethyl benzene. As alcohol as the good solvent medium, for example, methanol, ethanol, propanol and butanol, etc. may be mentioned.

Note that when mineral spirits (MSP) is include as the poor solvent medium, it is preferable that the mineral spirits alone is included in a range of larger than 7% but not larger than 15% with respect to the entire solvent. When the adding quantity of MSP is too small, breathability tends to decline, while when the adding quantity is too large, it is liable that the sheet surface smoothness declines and films are hard to be formed thick.

The poor solvent medium is included in a range of preferably 20 to 60 wt %, more preferably 20 to 50 wt %, and furthermore preferably 30 to 50 wt % with respect to the entire solvent. When the weight % of the poor solvent medium is too small, the breathability tends to decline, while when too large, it is liable that the filtering property declines and suitable slurry in terms of molding a sheet cannot be obtained.

In the present embodiment, by setting a content of the poor solvent medium included in the green sheet slurry to 20 to 60 wt %, pre-compression sheet density (ρg1) of the pre-compression green sheet can become low. By compressing the low density pre-compression green sheet to obtain a compressed green sheet, a difference (Δρg) of sheet density before and after the compression and a later explained sheet contraction rate (Δρg/ρg1) can be improved, and the effects of the present invention can be furthermore enhanced.

In the present embodiment, the green sheet slurry may include a xylene based resin as adhesiveness aide in addition to the binder resin. The xylene based resin is added in a range of 1.0 wt % or smaller, preferably 0.1 to 1.0 wt %, and particularly preferably larger than 0.1 but not larger than 1.0 wt % with respect to 100 parts by weight of the ceramic powder. When the adding quantity of the xylene based resin is too small, the adhesiveness tends to decline. While when the adding quantity is too large, the adhesiveness improves, however, it is liable that surface roughness of the sheet becomes rough, it becomes difficult to stack a large number of layers, tensile strength of the sheet declines and handleability of the sheet declines.

The green sheet slurry may include additives selected from a variety of dispersants, plasticizers, antistatic agents, dielectrics, glass flits and insulators in accordance with need.

In the present embodiment, dispersants are not particularly limited, but polyethylene glycol based nonionic dispersants are preferably used, and a value of the hydrophilic property/lipophilic property balance (HLB) is 5 to 6. Dispersants are added in an amount of preferably 0.5 part by weight or larger and 1.5 parts by weight or smaller, and more preferably 0.5 parts by weight or larger and 1.0 parts by weight or smaller with respect to 100 parts by weight of ceramic powder.

When the HLB is out of the above ranges, it is liable that the slurry viscosity increases and the sheet surface roughness increases. Also, other dispersants than polyethylene glycol based nonionic dispersants are not preferable because the slurry viscosity increases, the sheet surface roughness increases, and a sheet elongation rate declines. When the adding quantity of the dispersant is too small, the sheet surface roughness tends to increase, while when too large, the sheet tensile strength and stackability tend to decline.

In the present embodiment, as a plasticizer, dioctyl phthalate is preferably used and is included in an amount of preferably 40 parts by weight or larger and 70 parts by weight or smaller, more preferably 40 to 60 parts by weight with respect to 100 parts by weight of the binder resin. Comparing with other plasticizers, dioctyl phthalate is preferable in both of the sheet strength and sheet elongation, and is particularly preferable because the release strength from the supporter is small for being easily released. Note that when the content of the plasticizer is too small, it is liable that the sheet elongation becomes small and flexibility declines. While when the content is too large, it is liable that the plasticizer breeds out from the sheet, segregation of the plasticizer to the sheet easily arises, and dispersibility of the sheet declines.

Also, in the present embodiment, the green sheet slurry contains water in an amount of 1 part by weight or larger and 6 parts by weight or smaller, preferably 1 to 3 parts by weight with respect to 100 parts by weight of dielectric powder. When the content of water is too small, it is liable that changes of slurry characteristics due to moisture absorbent over time become large, slurry viscosity increases, and filtering characteristics of the slurry declines. While when the water content is too large, it is liable that separation and precipitation of the slurry arise, dispersibility declines, and sheet surface roughness declines.

Furthermore, in the present embodiment, at least one of a hydrocarbon based solvent, industrial gasoline, kerosene and solvent naphtha is added in an amount of preferably 3 parts by weight or larger and 15 parts by weight or smaller, and more preferably 5 to 10 parts by weight with respect to 100 parts by weight of the dielectric powder. By adding these additives, sheet strength and sheet surface roughness can be improved. When the adding quantity of the additives is too small, effects of adding is small, while when too large, it is liable that the sheet strength and sheet surface roughness inversely declined.

The binder resin is included in an amount of preferably 4 to 6.5 parts by weight, and more preferably 4 to 6 parts by weight with respect to 100 parts by weight of the ceramic powder. When the adding quantity of the binder resin is too small, it is liable that sufficient strength and adhesiveness in terms of molding and processing sheets cannot be obtained, while when too large, strength of the sheet tends to become too large.

Also, when assuming that a total volume of the ceramic powder, binder resin and plasticizer is 100 volume %, the volume ratio of the dielectric powder is preferably 62.42% or higher and 72.69% or lower, and more preferably 63.93% or higher and 72.69% or lower. When the volume ratio is too small, it is liable that segregation of the binder easily arises, dispersibility declines, and surface roughness declines. While, when the volume ratio is too large, it is liable that the sheet strength declines and adhesiveness at the time of stacking layers deteriorates.

Furthermore, in the present embodiment, the green sheet slurry preferably includes an antistatic agent, and the antistatic agent is preferably an imidazoline based antistatic agent. When the antistatic agent is not an imidazoline based antistatic agent, an antistatic effect is small and sheet strength, sheet elongation degree or adhesiveness tends to decline.

The antistatic agent is included in an amount of 0.1 part by weight or larger and 0.75 part by weight or smaller, and more preferably 0.25 to 0.5 part by weight. When an adding quantity of the antistatic agent is too small, the antistatic effect becomes small, while when too large, it is liable that the sheet surface roughness declines and the sheet strength declines. When the antistatic effect in too small, static electricity easily arises at the time of removing a carrier sheet as a supporter from the ceramic green sheet and disadvantages, such that wrinkles arise on the green sheet, easily arise.

To prepare the green sheet slurry, first, ceramic powder is dispersed in the slurry by a ball-mill, etc. (pigment dispersion step). The pigment dispersion step is also a pulverizing step of the ceramic powder (pigment) at the same time, and the progress can be also acquired from changes of an average particle diameter of the ceramic powder.

Next, in the slurry containing the ceramic powder, a dispersant and other additives are added and dispersed, so that a dispersion slurry is obtained (dispersant adding and dispersing step). Finally, the dispersion slurry is added with a binder resin and kneaded (resin kneading step), consequently, the green sheet slurry of the present embodiment is produced.

Next, the thus obtained green sheet slurry is used to produce the inner stacked body 100 and the outer stacked body 200 shown in FIG. 3.

Production of Inner Stacked Body 100

As shown in FIG. 3, the inner stacked body 100 is a stacked body in a green state produced by stacking compressed inner green sheets 2b and internal electrode layers 3 alternately.

In the present embodiment, the compressed inner green sheets 2b composing the inner stacked body 100 are green sheets produced by compressing the pre-compression green sheets 2a.

Below, a production method of the inner stacked body 100 will be explained.

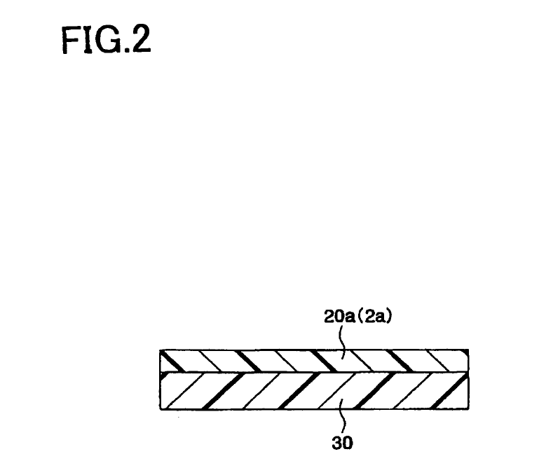

First, by using the green sheet slurry obtained as above, as shown in FIG. 2, an inner green sheet 2a is formed on a carrier sheet 30 as a supporter to be a thickness of preferably 0.5 to 30 μm, more preferably 0.5 to 10 μm or so by the doctor blade method, etc. The inner green sheet 2a is dried after being formed on the carrier sheet 30.

A drying temperature of the inner green sheet is preferably 50 to 100° C., and the drying time is preferably 1 to 20 minutes. A thickness of the inner green sheet after drying is contracted to 5 to 25% of the thickness before drying. A thickness of the pre-compression inner green sheet 2a after drying is preferably 3 μm or thinner.

Next, on one surface of the pre-compression inner green sheet 2a, an internal electrode layer 3 shown in FIG. 1 is formed. A method of forming the internal electrode layer 3 is not particularly limited and a printing method, thin film method and transfer method, etc. may be mentioned.

After that, as shown in FIG. 3, the pre-compression inner green sheets 2a, each having the internal electrode layer 3 formed thereon, are stacked alternately to form the inner stacked body 100.

In the present embodiment, when stacking the pre-compression inner green sheets 2a, the green sheets are compressed by a predetermined compression force to obtain compressed inner green sheets 2b. Namely, as shown in FIG. 3, the inner stacked body 100 is a stacked body, wherein the internal electrode layers 3 and the compressed inner green sheets 2b are alternately stacked. Note that, in the present embodiment, it is preferable that pre-compression sheet density (ρg1) of the pre-compression inner green sheet 2a and post-compression sheet density (ρg2) of the compressed inner green sheet 2b are adjusted to have the relationship below.

Namely, in the present embodiment, a sheet contraction rate (Δρg/ρg1) obtained by dividing a difference (Δρg: Δρg=ρg2−ρg1) of the pre-compression sheet density (ρg1) and the post-compression sheet density (ρg2) by the pre-compression sheet density (ρg1) is set to be 1% or higher, preferably 1.2% or higher, and more preferably 1.3% or higher. As a result of setting the sheet contraction rate (Δρg/ρg1) to be in the above range, handleability of the compressed inner green sheets 2b, particularly, adhesiveness (release strength) can be improved. Therefore, handleability, etc. of the inner stacked body 100 composed of the inner green sheets 2b and internal electrode layers 3 and the green sheet stacked body 300 can be improved.

The compression force at the time of compressing the green sheets are preferably 1 to 200 Pa, more preferably 2 to 200 Pa. When the compression force is too small, the sheet contraction rate (Δρg/ρg1) becomes too small and it is liable that the effects of the present invention cannot be obtained. Inversely, when the compression force is too large, the green sheet tends to be broken.

Other compression condition is a compression time of preferably 5 seconds to 120 minutes, more preferably 5 seconds to 60 minutes, and a compression temperature of preferably 50 to 100° C., more preferably 60 to 100° C. When the compression time is too short, the sheet compression ratio (Δρg/ρg1) becomes too small and it is liable that the effects of the present invention cannot be obtained. Inversely, when the compression time is too long, the production efficiency tends to decline. When the compression temperature is too low, the sheet compression ratio (Δρg/ρg1) becomes too low and it is liable that the effects of the present invention cannot be obtained. Inversely, when the compression temperature is too high, it is liable that a binder in the green sheets becomes soft by heating and it becomes difficult to keep a sheet shape.

In the present embodiment, it is sufficient that the pre-compression sheet density (ρg1) and the post-compression sheet density (ρg2) satisfy the condition that the sheet contraction rate (Δρg/ρg1) is in the predetermined range explained above and there is not particular limitation, but the pre-compression sheet density (ρg1) is preferably low. As a result that the pre-compression sheet density (ρg1) becomes low, a difference (Δρg) of the sheet densities before and after compression can become large and the sheet contraction rate (Δρg/ρg1) can be improved. Note that, in the present embodiment, attainment of low density of the green sheet means, for example, a sheet density of the green sheet after molding becomes low when using a ceramic powder having the sane density. An extent of low density of the green sheet is not particularly limited but, for example, a ratio (ρg1/ρ0) of the pre-compression sheet density (ρg1) of the pre-compression green sheet to the density (ρ0) of the ceramic powder is 0.5 to 0.65 or so.

Production of Outer Stacked Body 200

Next, the outer stacked body 200 shown in FIG. 3 is produced.

The outer stacked body 200 is, shown in FIG. 3, a stacked body in a green state composed of a plurality of the compressed outer green sheets 20b.

In the present embodiment, the plurality of compressed outer green sheets 20b composing the outer stacked body 200 are produced by compressing the pro-compression outer green sheets 20a.

Below, a production method of the outer stacked body 200 will be explained.

First, as shown in FIG. 2, by using the green sheet slurry obtained as explained above is used to form a pre-compression outer green sheet 20a on a carrier sheet 30 as a supporter to be a thickness of preferably 1 to 30 μm, more preferably 2 to 25 μm or so by the doctor blade method, etc. The outer green sheet 20a is dried after being formed on the carrier sheet 30 and removed. The carrier sheet 30 is composed, for example, of a PET film, etc.

A drying temperature of the outer green sheet 20a is preferably 50 to 100° C., and the drying time is preferably 1 to 20 minutes. A thickness of the outer green sheet after drying is contracted to 5 to 25% of the thickness before drying. A thickness of the pre-compression outer green sheet 20a after drying is preferably 10 μm or thicker.

Next, the obtained pre-compression outer green sheets 20a are stacked to produce the outer stacked body 200 shown in FIG. 3.

In the present embodiment, when stacking the pre-compression outer green sheets 20a, the green sheets are compressed by a predetermined compression force to obtain compressed outer green sheets 20b. Namely, as shown in FIG. 3, the outer stacked body 200 is a stacked body formed by a plurality of the compressed outer green sheets 20b. Note that, in the present embodiment, pre-compression sheet density (ρg1) of the pre-compression outer green sheet and post-compression sheet density (ρg2) of the compressed outer green sheet are adjusted to have the relationship below.

Namely, in the present embodiment, a sheet contraction rate (Δρg/ρg1) obtained by dividing a difference (Δρg: Δρg=ρg2−ρg1) of the pre-compression sheet density (ρg1) and the post-compression sheet density (ρg2) by the pre-compression sheet density (ρg1) is set to be 1% or higher, preferably 1.2% or higher, and more preferably 1.3% or higher. As a result of setting the sheet contraction rate (Δρg/ρg1) to be in the above range, handleability of the compressed outer green sheets 20b, particularly, adhesiveness (release strength) can be improved. Therefore, handleability, etc. of the outer stacked body 200 composed of the outer green sheets 20b and green sheet stacked body 300 can be improved. Particularly, it is efficient because the outer dielectric layers 20 are produced by using the outer green sheet having a relatively thick film thickness and required to have excellent handleability, such as high adhesiveness (release strength).

Note that the compression force at the time of compressing the outer green sheets, the compression time and compression temperature may be the same condition as those in the inner green sheets.

Also, the pre-compression sheet density (ρg1) of the pro-compression outer green sheets 20a is preferably low as in the case of the inner green sheets.

Next, as shown in FIG. 3, on both outer end portions in the stacking direction of the inner stacked body 100 produced as explained above, the thus produced outer stacked body 200 are stacked, so that a green sheet stacked body 300 is obtained.

Next, the thus obtained green sheet stacked body 300 is cut to a predetermined stacked body size to be a green chip, then, binder removal processing and firing are performed. Then, thermal treatment is performed to re-oxidize the dielectric layers 2 and 20.

The binder removal processing may be performed under a normal condition, but when N1, a N1 alloy or other base metal is used as a conductive material of the internal electrode layers, the condition below is particularly preferable.

Temperature raising rate: 5 to 300° C./hour, particularly 10 to 50° C./hour

Holding temperature: 200 to 400° C., particularly 250 to 350° C.

Holding time: 0.5 to 20 hours, particularly 1 to 10 hours

Atmosphere: wet mixed gas of N₂ and H₂.

A firing condition is preferably as below.

Temperature raising rate: 50 to 500® C./hour, particularly 200 to 300° C./hour

Holding temperature: 1100 to 1300° C., particularly 1150 to 1250° C.

Holding time: 0.5 to 8 hours, particularly 1 to 3 hours

Cooling rate: 50 to 500° C./hour, particularly 200 to 300° C./hour

Atmosphere: wet mixed gas of N₂ and H₂, etc.

Note that an oxygen partial pressure in the air at firing is preferably 10⁻² Pa or lower, particularly 10⁻² to 10⁻⁸ Pa. When exceeding the above range, the internal electrode layers tend to be oxidized, while when the oxygen partial pressure is too low, it is liable that an electrode material of the internal electrode layers results in abnormal sintering and broken.

The thermal treatment after the firing as above is preferably performed with a holding temperature or the highest temperature of 1000° C. or higher, more preferably 1000 to 1100° C. When the holding temperature or the highest temperature at the thermal treatment is lower than the range, oxidization of the dielectric material is insufficient and the insulation resistance lifetime tends to be short. While when exceeding the above range, not only Ni of the internal electrodes is oxidized to deteriorate the capacity, but it reacts with the dielectric base material, and the lifetime tends to be short as well. The oxygen partial pressure at the thermal treatment is higher than a reducing atmosphere at firing and preferably 10⁻³ Pa to 1 Pa, more preferably 10⁻² Pa to 1 Pa. When below the above ranges, re-oxidization of the dielectric layers 2 becomes difficult, while when exceeding the above ranges, the internal electrode layers 3 tend to be oxidized. Other condition at the thermal treatment is preferably as below.

Holding time: 0 to 6 hours, particularly 2 to 5 hours

Cooling rate: 50 to 500° C./hour, particularly 100 to 300° C./hour

Atmosphere: wet N₂ gas, etc.

Note that, for example, a wetter, etc. may be used to wet the N₂ gas and mixed gas, etc. In this case, the water temperature is preferably 0 to 75° C. or so. The binder removal processing, firing and annealing may be performed continuously or separately. When performing continuously, the preferable sequence is as follows: the atmosphere is changed without cooling after the binder removal processing, continuously, the temperature is raised to the holding temperature at firing to perform firing. Next, it is cooled and the thermal treatment is performed by changing the atmosphere when the temperature reaches to the holding temperature of the thermal treatment. On the other hand, when performing them separately, the preferable sequence is as follows: at the time of firing, after raising the temperature to the holding temperature of the binder removal processing in an atmosphere of a N₂ gas or a wet N₂ gas, the atmosphere is changed, and the temperature is furthermore raised. After that, after cooling the temperature to the holding temperature of the thermal processing, the cooling continues by changing the atmosphere again to a N₂ gas or a wet N₂ gas. Also, in the thermal processing, after raising the temperature to the holding temperature under the N₂ gas atmosphere, the atmosphere may be changed, or the entire process of the thermal processing may be in a wet N₂ gas atmosphere.

End surface polishing, for example, by barrel polishing or sand blast, etc. is performed on the sintered body (element body 10) obtained as above, and the terminal electrode slurry is burnt to form terminal electrodes 4. A firing condition of the terminal electrode slurry is preferably, for example, at 600 to 800° C. in a wet mixed gas of N₂ and H₂ for 10 minutes to 1 hour or so. A pad layer is formed by plating, etc. on the surface of the terminal electrodes 4 if necessary. Note that the terminal electrode slurry may be fabricated in the same way as in the case of the electrode slurry explained above.

A multilayer ceramic capacitor of the present invention produced as above is mounted on a print substrate, etc. by soldering, etc. and used for a variety of electronic apparatuses, etc.

Note that the present invention is not limited to the above embodiment and may be variously modified within the scope of the present invention.

For example, the method of the present invention is not limited to a production method of a multilayer ceramic capacitor and may be applied as a production method of other multilayer type electronic devices.

Also, in the above embodiment, the inner green sheets and outer green sheets were compressed at the time of stacking, respectively. However, compression of the respective green sheets may be performed after forming the inner stacked body 100 and outer stacked body 200 or after forming the green sheet stacked body 300.

Also, in the above embodiment, green sheets having a sheet contraction rate (Δρg/ρg1) of 1% or higher were used as the inner green sheets and outer green sheets. However, green sheets having a sheet contraction rate (Δρg/ρg1) of 1% or higher may be used in either one of the inner green sheets and outer green sheets or at least a part of the green sheets.

### EXAMPLES

Below, the present invention will be explained based on furthermore detailed examples, but the present invention is not limited to the examples.

### Example 1a

Production of Thick Film Green Sheet Slurry

As a starting material of the ceramic powder, BaTiO₃ powder (BT-05B of Sakai Chemical Industry Co., Ltd.) was used. Ceramic powder subcomponent additives were prepared to attain (Ba_{0.6}Ca_{0.4})SiO₃: 1.48 parts by weight, Y₂O₃: 1.01 parts by weight, MgCO₃: 0.72 wt %, Cr₂O₃: 0.13 wt % and V₂O₅: 0.045 wt % with respect to 100 parts by weight of the BaTiO₃ powder.

First, only the subcomponent additives were mixed with a ball-mill to obtain slurry. Namely, the subcomponent additives (total amount is 8.8 g), ethanol in an amount of 6 g, n-propanol in an amount of 6 g, xylene in an amount of 2 g and a dispersant (0.1 g) were preliminarily pulverized by a ball-mill for 20 hours.

As a binder, 15% lacquer (BH6 made by Sekisui Chemical Co., Ltd. was dissolved in ethanol/n-propanol-1:1) of BH6 (polyvinyl butyral resin/PVB) was used. Also, as a dispersant, a polyethylene glycol based nonionic dispersant (HLB=5 to 6) was used.

Next, BaTiO₃ in an amount of 191.2 g was added with the preliminarily pulverized subcomponent additives, ethanol in an amount of 37 g, n-propanol in an amount of 37 g, xylene+toluene in an amount of 50 g, mineral spirits (MSP) in an amount of 15 g, DOP (dioctyl phthalate) as a plasticizer component in an amount of 6 g, a polyethylene glycol based nonionic disprsant (HLB=5 to 6) in an amount of 1.4 g and solid content of 15% lacquer (BH6 made by Sekisui Chemical Co., Ltd. was dissolved in ethanol/n-propanol=1:1) of BH6 (polyvinyl butyral resin/PVB) in an amount of 6 parts by weight (Bog as an adding quantity of lacquer). After that, this dispersion slurry was mixed by a ball-mill for 20 hours, so that ceramic slurry (thick film green sheet slurry) was obtained. In the present example, an average particle diameter (D50 diameter) of the ceramic powder after dispersed in the slurry was 0.767 μm. The D50 diameter means an average particle diameter at 50% of entire volume of the ceramic powder and is defined, for example, by JIB R 1629, etc. The particle diameter was measured by the Microtrac HRA made by Nikkiso Co., Ltd.

A polymerization degree of the polyvinyl butyral resin as a binder resin included in the ceramic slurry was 1400, a butyralation degree thereof was 69%±3%, and a residual acetyl group amount was 3±2%. This binder resin was included in an amount of 6 parts by weight with respect to 100 parts by weight of the ceramic powder (including ceramic powder subcomponent additives).

Also, DOP as a plasticizer was included in an amount of 50 parts by weight with respect to 100 parts by weight of the binder resin. A polyethylene glycol based nonionic dispersant as a dispersant was included in an amount of 0.7 part by weight with respect to 100 parts by weight of the ceramic powder.

Also, as shown in Table 1, in the slurry, ethanol and n-propanol as the good solvent medium were included in an amount of 60.4 wt %, MSP as a part of the poor solvent medium was included in an amount of 9.1 wt %, and xylene and toluene as a part of the poor solvent medium and solvent medium having a high boiling point were included in an amount of 30.5 wt % in total with respect to the entire solvent. Namely, the poor solvent medium composed of MSP, xylene and toluene was included in an amount of 39.6 wt % with respect to the entire solvent.

TABLE 1
Table 1

| | Solvent Data | | | | | |
|---|---|---|---|---|---|---|
| | Poor Solvent | | | | Pigment Property | |
| | Medium | MSP Adding | Poor Solvent | Xylene and Toluene | | Slurry |
| | Quantity | Quantity | Medium Other | Quantity | Base | Pigment D50 |
| | [wt %] | [wt %] | Than MSP | [wt %] | Material | [μm] |
| Example 1 a | 39.6 | 9.1 | Xylene + Toluene | 30.5 | BT-05B | 0.763 |
| Example 1 b | 30.3 | 9.1 | Xylene + Toluene | 21.2 | BT-05B | 0.769 |
| Example 1 c | 21.0 | 9.1 | Xylene | 11.9 | BT-05B | 0.767 |
| Example 1 d | 39.1 | 9.1 | Xylene + Toluene | 30.0 | BT-035 | 0.547 |
| Example 1 e | 29.7 | 9.1 | Xylene + Toluene | 20.6 | BT-035 | 0.552 |
| Example 1 f | 20.3 | 9.1 | Xylene | 11.2 | BT-035 | 0.548 |
| Example 1 g | 38.6 | 9.1 | Xylene + Toluene | 29.5 | BT-02 | 0.441 |
| Comparative | 29.2 | 9.1 | Xylene + Toluene | 20.1 | BT-02 | 0.438 |
| Example 1 a | | | | | | |
| Comparative | 19.7 | 9.1 | Xylene | 10.6 | BT-02 | 0.444 |
| Example 1 b | | | | | | |

TABLE 2
Table 2

| | Poor Solvent | | | | | Sheet | |
|---|---|---|---|---|---|---|---|
| | Medium | Slurry | | ρ g2 | | Contraction | |
| | Quantity in | Pigment | | (Compression | | Rate | Release |
| | Solvent | D50 | ρ g1 | Force 4 MPa) | Δ ρ g | (Δ ρ g/ρ g1) | Strength |
| | [wt %] | [μm] | [g/cm³] | [g/cm³] | [g/cm³] | [%] | [N/cm²] |
| Example 1 a | 39.6 | 0.763 | 3.36 | 3.51 | 0.15 | 4.46 | 28.3 |
| Example 1 b | 30.3 | 0.769 | 3.43 | 3.56 | 0.13 | 3.79 | 30.5 |
| Example 1 c | 21.0 | 0.767 | 3.47 | 3.58 | 0.11 | 3.17 | 28.8 |
| Example 1 d | 39.1 | 0.547 | 3.28 | 3.34 | 0.06 | 1.83 | 26.7 |
| Example 1 e | 29.7 | 0.552 | 3.33 | 3.39 | 0.06 | 1.80 | 23.6 |
| Example 1 f | 20.3 | 0.548 | 3.38 | 3.45 | 0.07 | 2.07 | 21.2 |
| Example 1 g | 38.6 | 0.441 | 3.07 | 3.11 | 0.04 | 1.30 | 15.1 |
| Comparative | 29.2 | 0.438 | 3.15 | 3.16 | 0.01 | 0.32 | 8.7 |
| Example 1 a | | | | | | | |
| Comparative | 19.7 | 0.444 | 3.19 | 3.20 | 0.01 | 0.31 | 1.5 |
| Example 1 b | | | | | | | |

Production of Pre-Compression Green Sheet

The slurry obtained as above was applied on a PET film (carrier sheet) as a supporting film by the doctor blade method and dried so as to produce a pre-compression green sheet. Note that, in the present example, a thickness of the pre-compression green sheet was 10 μm.

Compression of Green Sheet

Two of the thus obtained pre-compression green sheets were compressed by using a four-column type hydraulic molding machine an a compression device under a condition of a compression force of 4 MPa, compression time of 1 minute and compression temperature of 70° C., so that a compressed green sheet stacked body sample composed of two compressed green sheets was obtained.

Sheet Density of Green Sheet Before and After Compression

Densities of the pre-compression green sheet and the compressed green sheet stacked body sample produced as above were measured, and pre-compression sheet density (ρg1) and compressed sheet density (ρg2) were obtained. Note that each sheet density (unit is g/cm³) was calculated from measured values of weight and volume of the sheet.

Measurement of Release Strength of Adhesiveness

Release strength of adhesiveness (unit is N/cm²) was evaluated as below. First, the compressed green sheet stacked body sample produced as above was prepared. Then, a two-sided tape was put on a surface of the compressed green sheet stacked body sample, and a tensile testing device 5543 of Instron Corporation was used to draw in the splitting direction of respective sets of sheets. Release strength at the time of splitting was measured. The higher the release strength, the more excellent the adhesiveness is.

### Examples 1b and 1c

Other than changing a kind (xylene+toluene, or xylene alone) and adding quantity of a part of the poor solvent medium in the solvent as shown in Table 1, ceramic slurry was produced in the same way as in the example 1a. Next, the obtained ceramic slurry was used to produce pre-compression green sheets and compressed green sheet stacked body samples in the same way as in the example 1a, and sheet density and release strength were measured, respectively. The results are shown in Table 1 and Table 2. Note that, in the examples 1b and 1c, average particle diameters (D50 diameter) of ceramic powder after dispersed in the slurry were 0.769 μm and 0.767 μm, respectively.

### Examples 1d to 1f

Other than using BaTiO₃ powder (BT-035 of Sakai Chemical Co., Ltd.) having a different particle diameter from that of the BaTiO₃ used in the example 1a and changing a kind (xylene+toluene, or xylene alone) and adding quantity of a part of the poor solvent medium in the solvent as shown in Table 1, ceramic slurry was produced in the same way as in the example 1a. Next, the obtained ceramic slurry was used to produce pre-compression green sheets and compressed green sheet stacked body samples in the same way as in the example 1a, and sheet density and release strength were measured, respectively. The results are shown in Table 1 and Table 2. Note that, in the examples 1d, 1e and 1f, average particle diameters (D50 diameter) of ceramic powder after dispersed in the slurry were 0.547 μm, 0.552 μm and 0.548 μm, respectively.

### Example 1g, Comparative Examples 1a and 1b

Other than using BaTiO₃ powder (BT-02 of Sakai Chemical Co., Ltd.) having a different particle diameter from that of the BaTiO₃ used in the example 1a and changing a kind (xylene+toluene, or xylene alone) and adding quantity of a part of the poor solvent medium in the solvent as shown in Table 1, ceramic slurry was produced in the same way as in the example 1a. Next, the obtained ceramic slurry was used to produce pre-compression green sheets and compressed green sheet stacked body samples in the same way as in the example 1a, and sheet density and release strength were measured, respectively. The results are shown in Table 1 and Table 2. Note that, in the example 1g and comparative examples 1a and 1b, average particle diameters (D50 diameter) of ceramic powder after dispersed in the slurry were 0.441 μm, 0.438 μm and 0.444 μm, respectively.

Evaluation 1

As shown in Table 1 and Table 2, all of the examples 1a to 1g having a sheet contraction rate (Δρg/ρg1) of 1% or higher exhibited release strength of 10 N/cm² or larger, which is preferable result. Note that the sheet contraction rate (Δρg/ρg1) in the present example is a ratio of a difference (ΔΣg: Δρg=ρg2−ρg1) of a pre-compression sheet density (ρg1) and a post-compression sheet density (ρg2) to the pre-compression sheet density (ρg1).

On the other hand, the comparative examples 1a and 1b having a sheet contraction rate (Δρg/ρg1) of lower than 1% exhibited release strength of smaller than 10N/cm², which is poor in adhesiveness strength.

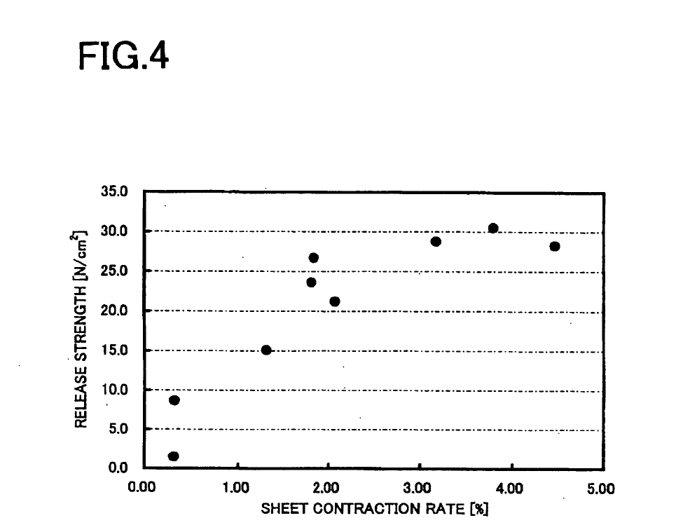

Note that, in the present example, from Table 2 and FIG. 4, it is confirmed that the release strength tends to become large as the sheet contraction rate becomes high to an extent that the sheet contraction rate (Δρg/ρg1) is 5% or so.

It was confirmed from the results that by compressing the green sheets to give a sheet contraction rate (Δρg/ρg1) of 1% or higher, preferably 1.2% or higher, adhesiveness (release strength) of the green sheet can be improved.

Note that by comparing the examples 1d to 1f, example 1g and comparative examples 1a and 1b using the same material as the BaTiO₃ powder, it is confirmed that by setting an adding quantity of the poor solvent medium in the solvent to 20 to 60 wt %, particularly 30 wt % or larger, the pre-compression sheet density (ρg1) can be made low and, particularly, effects of the present invention can be enhanced.

Namely, in the example 1d, wherein an adding quantity of the poor solvent medium is 39.1 wt %, the pre-compression sheet density (ρg1) can be made lower comparing with that in the examples 1e and 1f, wherein an adding quantity of the poor solvent medium is smaller than 30 wt %, and the release strength results in large though the sheet contraction rate is the same as or a bit lower than that in the examples 1e and 1f.

Also, in the example 1g, wherein an adding quantity of the poor solvent medium is 38.6 wt %, the pre-compression sheet density (ρg1) can be made lower comparing with that in the comparative example 1a, wherein an adding quantity of the poor solvent medium is smaller than 30 wt %, and the comparative example 1b, wherein an adding quantity of the poor solvent medium is smaller than 20 wt %, and the sheet contraction rate exceeded 1% and release strength also exceeded 10 N/cm². On the other hand, samples, wherein an adding quantity of the poor solvent medium was particularly smaller than 20 wt %, exhibited the sheet contraction rate of lower than 1% and the release strength of smaller than 10 N/cm².

### Examples 1a-2 and Example 1b-2

Other than changing the compression force at the time of compressing the pre-compression green sheets to 2 MPa, compressed green sheet stacked body samples were produced in the same way as in the examples 1a and 1b and sheet density and release strength were measured, respectively. The results are shown in Table 3. Note that Table 3 also shows results of the examples 1a and 1b with a compression force of 4 MPa.

TABLE 3
Table 3

| | | | | | Sheet | |
|---|---|---|---|---|---|---|
| | Compression | | | | Contration | Release |
| | Force | ρ g1 | ρ g2 | Δ ρ g | Rate | Strength |
| | [MPa] | [g/cm³] | [g/cm³] | [g/cm³] | [%] | [N/cm²] |
| Example 1 a | 4 | 3.36 | 3.51 | 0.15 | 4.46 | 28.3 |
| Example 1 a-2 | 2 | 3.36 | 3.49 | 0.13 | 3.87 | 23.9 |
| Example 1 b | 4 | 3.43 | 3.56 | 0.13 | 3.79 | 30.5 |
| Example 1 b-2 | 2 | 3.43 | 3.53 | 0.10 | 2.92 | 21.6 |

Evaluation 2

From Table 3, the examples 1a-2 and 1b-2 with a compression force of 2 MPa exhibited a sheet contraction rate (Δρg/ρg1) exceeding 1% and release strength exceeding 10 N/cm² in the same way as those in the examples 1a and 1b with a compression force of 4 MPa. From the results, it was confirmed that the effects of the present invention can be obtained even when the compression force was changed.

1. A production method of a green sheet, comprising the steps of:
preparing a pre-compression green sheet including ceramic powder and a binder resin; and
compressing said pre-compression green sheet to obtain a compressed green sheet;
wherein:
a difference (Δpg) between a pre-compression sheet density (pg1) of said pre-compression green sheet and a post-compression sheet density (pg2) of said compressed green sheet is expressed by Δpg=(pg2) of said compressed green sheet is expressed by Δpg=pg2−pg1; and
a sheet contraction rate (Δpg/ρg1) as a ratio of the difference (Δpg) to said pre-compression sheet density (pg1) is 1% or higher.

2. The production method of a green sheet as set forth in claim 1, wherein said pre-compression green sheet is compressed by 1 to 200 MPa.

3. The production method of a green sheet as set forth in claim 1, wherein a thickness of said pre-compression sheet is 1 to 30 μm.

4. The production method of a green sheet as set forth in claim 1, wherein an average particle diameter (D50 diameter) of said ceramic powder is 0.1 to 1.0 μm.

5. The production method of a green sheet as set forth in claim 1, wherein a content of said binder resin in said pre-compression green sheet is 4 to 6.5 parts by weight with respect to 100 parts by weight of said ceramic powder.

6. The production method of a green sheet as set forth in claim 1, further comprising the steps of:
preparing green sheet slurry including said ceramic powder, said binder resin and a solvent; and
forming said pre-compression green sheet by using said green sheet slurry;
wherein:
said binder resin includes a butyral based resin as its main component;
said solvent includes a good solvent medium for said binder resin to be dissolved well and a poor solvent medium giving poorer solubility to said binder resin comparing with said good solvent medium; and
said poor solvent medium is included in a range of 20 to 60 wt % with respect to entire solvent.

7. A green sheet produced by the method as set forth in claim 1.

8. A production method of an electronic device, comprising the steps of:
stacking internal electrode layers and green sheets to obtain a green chip; and
firing said green chip;
wherein the green sheet as set forth in claim 7 is used as at least a part of said green sheet.

9. A production method of an electronic device, comprising the steps of:
stacking inner green sheets via internal electrode layers to obtain an inner stacked body;
stacking outer green sheets on both end surfaces in the stacking direction of said inner stacked body to obtain a green chip; and
firing said green chip;
wherein the green sheet as set forth in claim 7 is used as at least a part of said green sheet.

10. A production method of an electronic device, comprising the steps of:
stacking internal electrode layers and green sheets to obtain a green chip; and
firing said green chip;
wherein:
a difference (Δpg) between a pre-compression sheet density (pg1) of said green sheet before compression and a post-compression sheet density (pg2) of said green sheet after compression is expressed by Δpg=pg2−pg1; and
a compression force is applied to said green sheets, so that a sheet contraction rate (Δpg) to said pre-compression sheet density (pg1) become 1% or higher.

11. A production method of an electronic device, comprising the steps of:
stacking inner green sheets via internal electrode layers to obtain an inner stacked body;
stacking outer green sheets on both end surfaces in the stacking direction of said inner stacked body to obtain a green chip; and
firing said green chip;
wherein:
a difference (Δpg) between a pre-compression sheet density (pg1) of said outer green sheet before compression and a post-compression sheet density (pg2) of said outer green sheet after compression is expressed by Δpg=pg2−pg1; and
a compression force is applied to said outer green sheets, so that a sheet contraction rate (Δpg/pg1) as a ratio of the difference (Δpg) to said pre-compression sheet density (pg1) becomes 1% or higher.
